(19) United States
(12) Patent Application Publication
(10) Pub. No.: US 2024/0047474 A1
(43) Pub. Date: Feb. 8, 2024

(54) ARRAY SUBSTRATE, DISPLAY PANEL AND DISPLAY DEVICE

(71) Applicant: TIANMA ADVANCED DISPLAY TECHNOLOGY INSTITUTE (XIAMEN) CO., LTD., Xiamen (CN)

(72) Inventors: Zhenyu JIA, Xiamen (CN); Rusheng LIU, Xiamen (CN); Kerui XI, Xiamen (CN); Tianyi WU, Xiamen (CN); Xiaoxiang HE, Xiamen (CN); Liwei ZHANG, Xiamen (CN); Yukun HUANG, Xiamen (CN); Aowen LI, Xiamen (CN); Ping AN, Shanghai (CN); Xuhui PENG, Shanghai (CN)

(73) Assignee: TIANMA ADVANCED DISPLAY TECHNOLOGY INSTITUTE (XIAMEN) CO., LTD., Xiamen (CN)

(21) Appl. No.: 18/488,974

(22) Filed: Oct. 17, 2023

(30) Foreign Application Priority Data
Jun. 30, 2023 (CN) 202310796960.2

(51) Int. Cl. H01L 27/12; H01L 25/16; H01L 25/075; H01L 33/62

(52) U.S. Cl. CPC H01L 27/124; H01L 25/167; H01L 25/0753; H01L 33/62; H01L 27/1255

(57) ABSTRACT

An array substrate, a display panel and a display device are provided. The array substrate includes a semiconductor pattern, a first gate, a second gate and a first metal part. The semiconductor pattern includes a first channel overlapping with the first gate, a second channel overlapping with the second gate, and a first connection part connecting the first channel with the second channel. The first metal part overlaps with the first connection part and is electrically connected to the first connection part. According to the embodiments of the present disclosure, it is beneficial to improving the uniformity of current distribution of a transistor.

This application claims priority to Chinese Patent Application No. 202310796960.2, titled “ARRAY SUBSTRATE, DISPLAY PANEL AND DISPLAY DEVICE”, filed on Jun. 30, 2023 with the China National Intellectual Property Administration, which is hereby incorporated by reference in its entirety.

### FIELD

The present disclosure relates to the field of display technologies, and in particular to an array substrate, a display panel and a display device.

### BACKGROUND

With the continuous update of display technologies, user requirements on the display quality also increase.

A pixel circuit is provided in an array substrate to drive a light emitting device. The pixel circuit may include a transistor. However, in the conventional technology, the transistor has a problem of uneven current distribution in an on state, which affects the display quality.

### SUMMARY

According to embodiments of the present disclosure, an array substrate, a display panel and a display device are provided.

In one embodiment, an array substrate is provided according to an embodiment of the present disclosure. The array substrate includes a semiconductor pattern, a first gate, a second gate and a first metal part. The semiconductor pattern includes a first channel overlapping with the first gate, a second channel overlapping with the second gate, and a first connection part connecting the first channel and the second channel. The first metal part overlaps with the first connection part and is electrically connected to the first connection part.

In another embodiment, a display panel is provided according to an embodiment of the present disclosure. The display panel includes the array substrate according to the embodiments; and a light emitting device, where a pixel circuit in the array substrate is configured to drive the light emitting device to emit light.

In yet another embodiment, a display device is provided according to an embodiment of the present disclosure. The display device includes the display panel according to the embodiments.

### BRIEF DESCRIPTION OF THE DRAWINGS

Other embodiments of the present disclosure will become more apparent by reading the following detailed description of the non-restrictive embodiments with reference to the drawings, where the same or similar reference numerals represent the same or similar features, and the drawings are not drawn to actual scale.

FIG. 1 shows a schematic top view of an array substrate according to an embodiment of the present disclosure;

FIG. 2 is a schematic diagram showing connection of a transistor in an array substrate according to an embodiment of the present disclosure;

FIG. 3 shows a schematic cross-sectional view taken along line A-A in FIG. 1;

FIG. 4 shows a schematic diagram of a preparation process of a semiconductor pattern in an array substrate according to an embodiment of the present disclosure;

FIG. 5 is a schematic diagram showing current of a semiconductor pattern in an array substrate according to an embodiment of the present disclosure;

FIG. 6 shows a schematic top view of an array substrate according to another embodiment of the present disclosure;

FIG. 7 shows a schematic top view of an array substrate according to another embodiment of the present disclosure;

FIG. 8 shows a schematic top view of an array substrate according to another embodiment of the present disclosure;

FIG. 9 shows a schematic top view of an array substrate according to another embodiment of the present disclosure;

FIG. 10 shows a schematic cross-sectional view taken along line B-B in FIG. 9;

FIG. 11 shows a schematic top view of an array substrate according to another embodiment of the present disclosure;

FIG. 12 shows a schematic structural diagram of a pixel circuit in an array substrate according to an embodiment of the present disclosure;

FIG. 13 shows a schematic top view of an array substrate according to another embodiment of the present disclosure;

FIG. 14 shows a schematic cross-sectional view taken along line C-C in FIG. 13;

FIG. 15 shows a schematic top view of an array substrate according to another embodiment of the present disclosure;

FIG. 16 shows a schematic cross-sectional view taken along line D-D in FIG. 15;

FIG. 17 shows a schematic structural diagram of a display panel according to an embodiment of the present disclosure; and

FIG. 18 shows a schematic structural diagram of a display device according to an embodiment of the present disclosure.

Reference numerals are listed as follows:

| | | | | | |
|---|---|---|---|---|---|
| 100 | Array substrate; | | | | |
| 10 | Semiconductor pattern; | | | | |
| 11 | First channel; | 12 | Second channel; | 13 | Third channel; |
| 14 | First connection part; | 15 | Second connection part; | | |
| 16 | Electrode connection | 161 | First electrode | 162 | Second electrode |
| | part; | | connection part; | | connection part; |
| 21 | First gate; | 22 | Second gate; | 23 | Third gate; |
| 31 | First metal part; | 311 | First sub-metal part; | 312 | Second sub-metal part; |
| 32 | Second metal part; | | | | |
| 33 | Electrode metal part; | 331 | First electrode | 332 | Second electrode |
| | | | metal part; | | metal part; |
| 34 | Bridge metal part; | | | | |
| 40 | Pixel circuit; | | | | |
| 01 | Substrate; | 02 | Driving device layer; | | |
| 200 | Display panel; | 201 | Light emitting device; and | | |
| 1000 | Display device. | | | | |

### DETAILED DESCRIPTION OF EMBODIMENTS

The features and exemplary embodiments of the present disclosure are described in detail below. To make the embodiments of the present disclosure more clear and apparent, the present disclosure is described in detail in conjunction with the drawings and the embodiments. It should be understood that the embodiments described herein are only intended to explain the present disclosure rather than to limit the present disclosure. Embodiments of the present disclosure may be implemented without some of these specific details. The following description of the embodiments is only intended to provide better understanding of the present disclosure by illustrating embodiments of the present disclosure.

It should be noted that, the relationship terms such as “first” and “second” are used for distinguishing an entity or operation from another entity or operation, rather than requiring or implying an actual relationship or order between these entities or operations. Further, the terms “include”, “comprise” or any variant thereof are intended to encompass nonexclusive inclusion so that a process, method, article or apparatus including a series of elements includes not only those elements but also other elements which have not been listed definitely or an element(s) inherent to the process, method, article or apparatus. Unless expressively limited otherwise, a process, method, article or apparatus limited by “comprising/including a(n) . . . ” does not exclude existence of another identical element in such process, method, article or apparatus.

It should be understood that in description of the structure of the component, when a layer or an area is referred to be “on” or “above” another layer or another area, it may be directly above the another layer or the another area, or other layers or areas may be included between the layer or the area and the another layer or the another area. And, if the component is flipped, the layer or the area may be located above or below the another layer or the another area.

It should be understood that the term “and/or” used in the present disclosure is only an association relationship to describe the associated objects, indicating that there may be three kinds of relationships, for example, A and/or B may indicate three cases, such as A exists alone, A and B exist at the same time, and B exists alone. In addition, the character “/” in this specification indicates that the associated objects before and after the character “/” are in an “or” relationship.

In the embodiments of the present disclosure, the term “electrical connection” may refer to a direct electrical connection between two components or an electrical connection between two components via one or more other components. The term “pattern” may refer to a “member”.

Various modifications and changes may be made to the present disclosure without departing from the spirit or scope of the present disclosure. Therefore, the present disclosure is intended to cover modifications and changes of the embodiments, which fall within the scope of the appended claims (the claimed embodiments) and their equivalents. It should be noted that the implementations provided in the embodiments of the present disclosure may be combined with each other as long as there is no conflict among them.

Before explaining the embodiments of the present disclosure, in order to facilitate the understanding of the embodiments of the present disclosure, problems existing in the related technologies are first explained in the present disclosure.

For example, in the Micro Light Emitting Diode (Micro LED) display technology, width-to-length ratios of channels of some transistors in a pixel circuit may be increased. For example, widths of channels of some transistors may be increased to improve their power supply capability, to meet the requirements of the Micro LED for large working current.

In order to save space, channels of different transistors with an electrical connection relationship in the pixel circuit may be connected through a semiconductor connection part. That is, a connection part including a semiconductor material, instead of a metal crossover line, is used as a connection line between transistors, and an electrical connection between different transistors is achieved by setting a via hole between a metal film layer and a semiconductor film layer.

However, it is found by inventors from research that the semiconductor connection part has a high square resistance, which easily leads to a problem of uneven current distribution of a transistor (in some embodiments, a transistor with a large width-to-length ratio of a channel) in an on state, resulting in a difference between the actual performance of the transistor and the simulation performance of the transistor, which further easily leads to a problem of display mura.

In order to solve the above problems, an array substrate, a display panel and a display device are provided according to the embodiments of the present disclosure. The embodiments of the array substrate, the display panel and the display device will be described below with reference to the drawings.

An array substrate according to an embodiment of the present disclosure is introduced first.

The array substrate according to the embodiment of the present disclosure may be applied to a display panel. The array substrate may include a circuit, and the circuit in the array substrate may be configured to drive a light emitting device in the display panel.

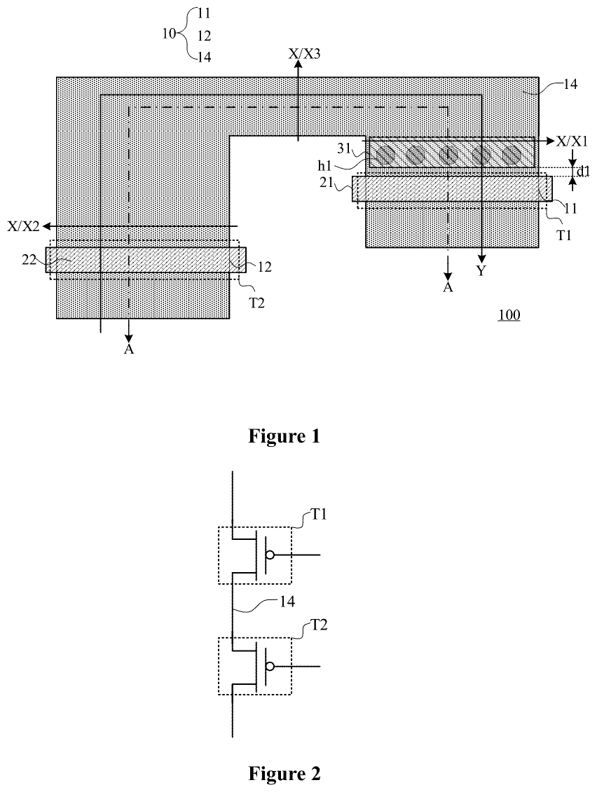

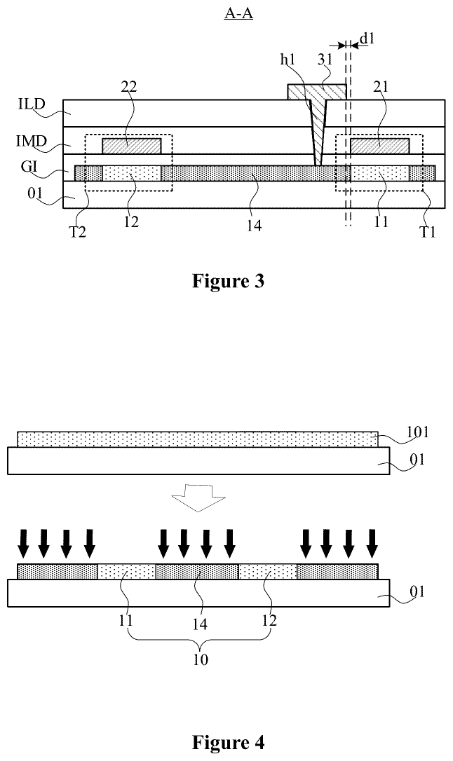

FIG. 1 shows a schematic top view of an array substrate according to an embodiment of the present disclosure. FIG. 2 is a schematic diagram showing connection of a transistor in an array substrate according to an embodiment of the present disclosure. FIG. 3 shows a schematic cross-sectional view taken along line A-A in FIG. 1. As shown in FIGS. 1, 2 and 3, an array substrate 100 may include a semiconductor pattern 10, a first gate 21, a second gate 22 and a first metal part 31.

The semiconductor pattern 10 includes a first channel 11, a second channel 12 and a first connection part 14. The first channel 11 overlaps with the first gate 21, and the second channel 12 overlaps with the second gate 22. The first connection part 14 connects the first channel 11 with the second channel 12.

The first metal part 31 overlaps with the first connection part 14, and the first metal part 31 is electrically connected to the first connection part 14.

It should be noted that the overlap of two components introduced in the embodiments of the present disclosure may mean that orthographic projections of the two components on a plane where the array substrate is located overlap.

It is to be understood that a material of the first metal part 31 includes a metal material.

The first channel 11 and the first gate 21 are components of a transistor T1, and the second channel 12 and the second gate 22 are components of a transistor T2. The first connection part 14 is a semiconductor connection part located between the first channel 11 and the second channel 12.

As shown in FIG. 2, the first connection part 14 is connected between the transistor T1 and the transistor T2.

It is to be understood that a material of the semiconductor pattern 10 includes a semiconductor material. That is, a material of each of the first channel 11, the second channel 12, and the first connection part 14 may include a semiconductor material. For example, the semiconductor pattern 10 may include Low Temperature Poly-Silicon (LTPS), amorphous silicon, metal oxide semiconductor (such as indium gallium zinc oxide) and other materials. The first channel 11 and the second channel 12 in the semiconductor pattern 10 have a semiconductor characteristic, and the first connection part 14 in the semiconductor pattern 10 has a conductor characteristic. The first connection part 14 may be a conductor structure formed by ion doping in an original semiconductor pattern. A conductivity of the first connection part 14 may be greater than a conductivity of the first channel 11 and a conductivity of the second channel 12. In a thickness direction of the array substrate, film layer positions of the first channel 11, the second channel 12 and the first connection part 14 may be the same, that is, the first channel 11, the second channel 12 and the first connection part 14 are located in a same film layer.

For example, a preparation process of the semiconductor pattern in the array substrate may be shown in FIG. 4. A body 101 of the semiconductor pattern may be formed on one side of a substrate 01 by using a semiconductor material, where the body 101 may be in a patterned shape. Then, a predetermined region in the body 101 of the semiconductor pattern is ion-doped to increase a conductivity of the predetermined region in the body 101 of the semiconductor pattern, to form a conductor, while a region in the body 101 of the semiconductor pattern that is not ion-doped still maintains its semiconductor characteristic. In an embodiment, an ion is implanted in a region where the first connection part 14 is to be formed, and the implanting process may be performed before or after forming a gate. In addition, ion is also implanted in a region except the channel, to obtain the first connection part 14. A region in the body 101 of the semiconductor pattern that is not implanted with the ion may be the channel.

It is found by inventors from research that the first connection part 14 still has a high square resistance of kiloohms even if the first connection part 14 is treated by ion implantation, which causes it difficult to ensure the uniformity of internal current of the transistor, in some embodiments, for the transistor with the large width-to-length ratio of the channel, leading to a difference between the simulation performance of the transistor (usually simulated under an ideal condition) and the actual performance of the transistor, and leading to a problem of display mura.

In an embodiment of the present disclosure, the first metal part 31 is additionally arranged, and the first metal part 31 is electrically connected to the first connection part 14, which is equivalent to thickening the first connection part 14, and a square resistance of the connection part connected to at least one end of a transistor can be reduced. Since current prefers to be transmitted in a material with low resistance, a current transmitting ability of the transistor can be enhanced, and the uniformity of current in the transistor is improved, to improve the performance of transistor, and improving the consistency between the actual performance and the simulation performance of the transistor, which is beneficial to improving the display quality in a case that the array substrate is used in the display panel.

In some embodiments, a conductivity of the first metal part 31 may be greater than a conductivity of the first connection part 14. A greater conductivity indicates a lower square resistance and a better conductive performance. Since the first metal part 31 has a higher conductivity, the characteristics of low square resistance and good conductivity of the first metal part 31 may be used to better improve the uniformity of current in the transistor.

In some embodiments, a potential of the first metal part 31 is floating. Here, “floating potential” means that the first metal part 31 is not electrically connected to other structures except the first connection part 14. Viewing from a metal layer where the first metal part 31 is located, the first metal part 31 is an isolated pattern. That is, the first metal part 31 is electrically connected only to the first connection part 14, and the potential of the first metal part 31 is the same as a potential of the first connection part 14. Since the potential of the first metal part 31 is floating, it is possible to avoid introducing other signals to the first connection part 14 through the first metal part 31, to avoid a potential disorder of the transistor connected to the first connection part 14.

In some embodiments, as shown in FIG. 1, a size of the first metal part 31 in a first direction X is larger than a size of the first metal part 31 in a second direction Y, the first direction X intersects with an extension direction of the semiconductor pattern 10, and the second direction Y is the same as the extension direction of the semiconductor pattern 10.

Here, the “extension direction” of the semiconductor pattern 10 may be understood as a direction in which the first channel 11, the first connection part 14 and the second channel 12 are arranged, i.e., a direction in which different functional regions in the semiconductor pattern 10 are arranged.

For example, as shown in FIG. 1, the first channel 11, the first connection part 14 and the second channel 12 may extend in the second direction Y, which is the “extension direction” of the semiconductor pattern 10. The first direction X intersects with the second direction Y. At different positions of the semiconductor pattern 10, the first direction X may direct towards different directions. As an example, the first direction X may include a first sub-direction X1, a second sub-direction X2 and a third sub-direction X3. In FIG. 1, at a position where the first metal part 31 is located, the first direction X is indicated by the first sub-direction X1.

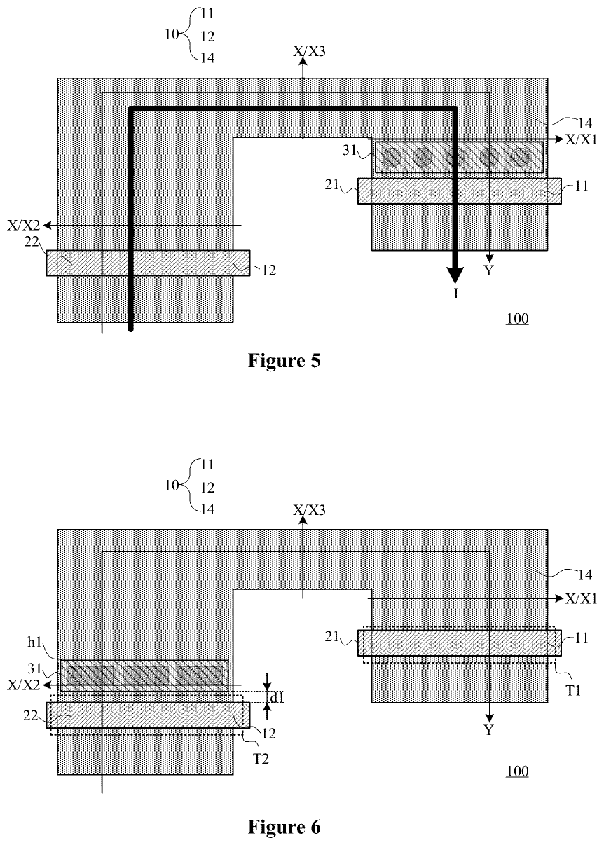

For example, as shown in FIG. 5, an overall flow direction of driving current I in the semiconductor pattern 10 may be indicated by an arrow, and the extension direction of the semiconductor pattern 10 may be the same as the overall flow direction of the driving current I in the semiconductor pattern 10.

For example, the current of the transistor may flow from a source of the transistor to a drain of the transistor, and the source and the drain of the transistor are located at both sides of the channel of the transistor respectively. A length of the channel of the transistor may be an interval between the source and the drain, a length direction of the channel of the transistor may be a direction in which the source and the drain of the transistor are arranged, and a width direction of the channel of the transistor may be perpendicular to the length direction of the channel.

Description is made by taking the first metal part 31 close to the first channel 11 as an example. The transistor T1 includes the first channel 11 and the first gate 21, an extension direction of the first metal part 31 is the first sub-direction X1, the first sub-direction X1 may be the width direction of the channel of the transistor T1, and the second direction Y may be the length direction of the channel of the transistor T1. A size of the first metal part 31 in the first sub-direction X1 is larger than a size of the first metal part 31 in the second direction Y. That is, the first metal part 31 is strip-shaped and may extend in the width direction of the channel of the transistor. For a transistor with a large width-to-length ratio of a channel, a width of the channel of the transistor is larger, and since the current prefers to be transmitted in a material with high conductivity, if the strip-shaped first metal part 31 extends in the width direction of the channel of the transistor, current distribution in the width direction of the channel of the transistor will be uniform.

It should be noted that, in the embodiments of the present disclosure, the first direction has the same meaning, the second direction has the same meaning, and the extension direction of the semiconductor pattern has the same meaning. The explanations of the respective directions are not repeated in the following embodiments.

In some embodiments, a size of the first metal part 31 in a first direction X is smaller than or equal to a size of the first connection part 14 in the first direction X, to avoid unnecessary enlargement of the first metal part 31, to reduce parasitic capacitance.

For example, an orthographic projection of the first metal part 31 on a plane where the semiconductor pattern 10 is located may be located in the semiconductor pattern 10.

It should be noted that, in the description that the size of the first metal part 31 in the first direction X is equal to the size of the first connection part 14 in the first direction X, “equal” here may include a size difference caused by a process error. That is, if the size difference between the two parts is within a process error range, sizes of the two parts may also be considered as being equal.

In some embodiments, as shown in FIG. 1, the first metal part 31 is spaced from the first gate 21 by an interval D1 in the extension direction of the semiconductor pattern 10. In an embodiment, as shown in FIG. 6, the first metal part 31 may be spaced from the second gate 22 by the interval d1 in the extension direction of the semiconductor pattern 10, where 1 um≤d1≤5 um.

That is, in the extension direction of the semiconductor pattern 10, the first metal part 31 may be disposed close to the transistor T1 where the first gate 21 is located (that is, in the extension direction of the semiconductor pattern 10, a distance between the first metal part 31 and the first gate 21 is smaller than a distance between the first metal part 31 and the second gate 22), or the first metal part 31 may be disposed close to the transistor T2 where the second gate 22 is located (that is, in the extension direction of the semiconductor pattern 10, a distance between the first metal part 31 and the second gate 22 is smaller than a distance between the first metal part 31 and the first gate 12).

For example, the first metal part 31 is used to improve the uniformity of current in the transistor T1. In a case that the interval between the first metal part 31 and the first gate 31 is large, an interval between the first metal part 31 and the first channel 11 is also large. In this case, a long first connection part 14 exists between the first metal part 31 and the first channel 11, which weakens the ability of the first metal part 31 to improve the uniformity of current in the transistor T1.

It is found by inventors from research that the first metal part 31 can better improve the uniformity of current in the transistor T1 under a condition that 1 um≤d1≤5 um.

It should be noted that a value of d1 is not absolute, and may be set based on the actual process capability.

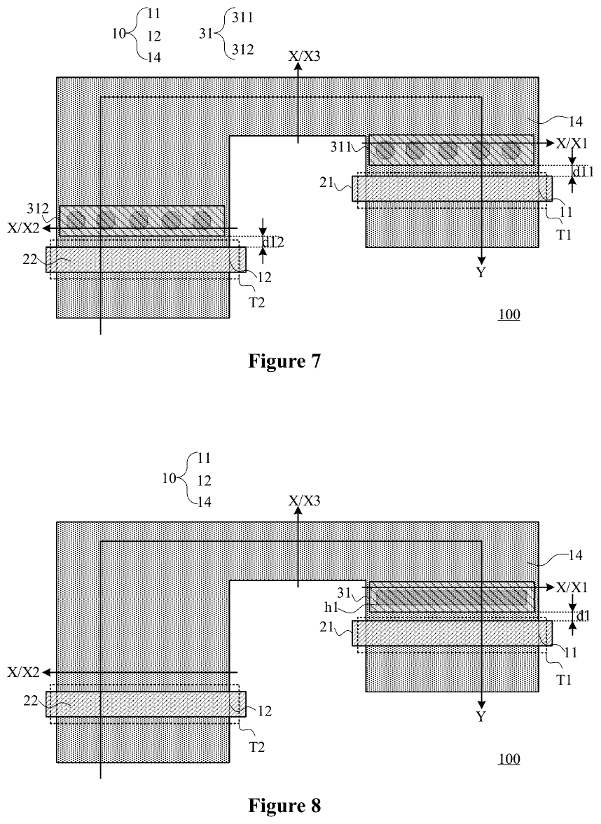

In some embodiments, as shown in FIG. 7, the first metal part 31 may include a first sub-metal part 311 and a second sub-metal part 312 which are spaced apart from each other. In the extension direction of the semiconductor pattern 10, a distance between the first sub-metal part 311 and the first channel 11 is smaller than a distance between the first sub-metal part 311 and the second channel 12, and a distance between the second sub-metal part 312 and the second channel 12 is smaller than a distance between the second sub-metal part 312 and the first channel 11.

That is, two sub-metal parts may be provided for the transistors T1 and T2 which are connected with each other. In one embodiment, the first sub-metal part 311 may be provided close to the transistor T1 where the first channel 11 is located, and the second sub-metal part 312 may be provided close to the transistor T2 where the second channel 12 is located. In this way, the first sub-metal part 311 may be used to improve the uniformity of current in the transistor T1 and the second sub-metal part 312 may be used to improve the uniformity of current in the transistor T2.

For example, in the extension direction of the semiconductor pattern 10, the first sub-metal part 311 and the first gate 21 may be spaced from each other by an interval d11, where 1 um≤d11≤5 um.

In the extension direction of the semiconductor pattern 10, the second sub-metal part 312 and the second gate 22 may be spaced from each other by an interval d12, where 1 um≤d12≤5 um.

In an embodiment, d11=d12.

In some embodiments, as shown in FIG. 1, the first metal part 31 may be electrically connected to the first connection part 14 through a first via hole h1. It can be understood that in this case, other film layers may be arranged between the first metal part 31 and the first connection part 14. For example, as shown in FIG. 3, an interlayer dielectric layer ILD and a capacitor insulating layer IMD may be arranged between the first metal part 31 and the first connection part 14. Both the interlayer dielectric layer ILD and the capacitor insulating layer IMD are insulating layers.

In an embodiment, an orthographic projection of the first via hole h1 on a plane where the semiconductor pattern 10 is located may have a circular shape, a strip shape or a polygonal shape, and the polygonal shape may include an octagon.

It should be noted that there may be no other film layer between the first metal part 31 and the first connection part 14. That is, the first metal part 31 may be in direct contact with the first connection part 14 (not shown in the drawings). In this case, there is no need to set a connection via hole between the first metal part 31 and the first connection part 14, which may be electrically connected through direct contact.

In some embodiments, as shown in FIG. 1, in a case that the first metal part 31 is electrically connected to the first connection part 14 through the first via hole h1, multiple first via holes h1 may be provided, and may be arranged in a first direction X, and the first direction X intersects with the extension direction of the semiconductor pattern 10.

For example, the first metal part 31 is used to improve the uniformity of current in the transistor T1. The first direction X may be the width direction of the channel of the transistor T1. In a case that the multiple first via holes h1 are arranged in the first direction X, the first metal part 31 and the first connection part 14 contact more through the first via holes h1 in the width direction of the channel of the transistor T1, and current distribution in the width direction of the channel of the transistor T1 is more uniform.

For example, the multiple first via holes h1 may be uniformly arranged in the first direction X, and an interval between every two adjacent first via holes h1 in the first direction X may be equal. If the process permits, the interval between two adjacent first via holes h1 in the first direction X may be made small enough.

For example, in a case that the multiple first via holes h1 are arranged in the first direction X, orthographic projections of the multiple first via holes h1 on a plane where the semiconductor pattern 10 is located may all be circular, or strip-shaped, or polygonal, which can reduce the process difficulty.

Of course, in other examples, orthographic projections of at least two first via holes h1 on the plane where the semiconductor pattern 10 is located may have different shapes.

In other embodiments, as shown in FIG. 8, an orthographic projection of the first via hole h1 on a plane where the semiconductor pattern 10 is located may have a strip shape, and an extension direction of the strip shape may intersect with the extension direction of the semiconductor pattern 10. For example, the strip-shaped orthographic projection of the first via hole h1 on the plane where the semiconductor pattern 10 is located extends in the first direction X.

In this case, only one strip-shaped first via hole h1 may be provided between the first metal part 31 and the first connection part 14, and the first metal part 31 and the first connection part 14 contact more through the first via hole h1 in the width direction of the channel of the transistor, and current distribution in the width direction of the channel of the transistor is more uniform.

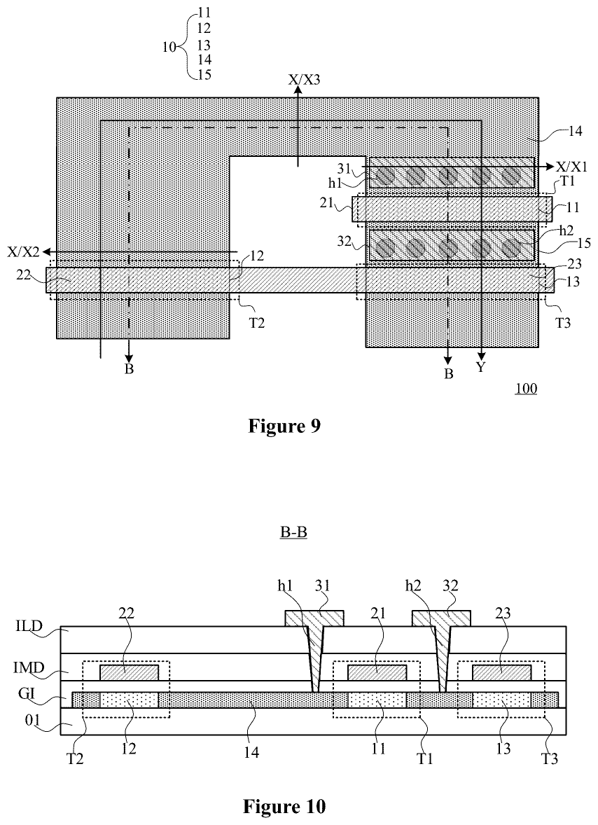

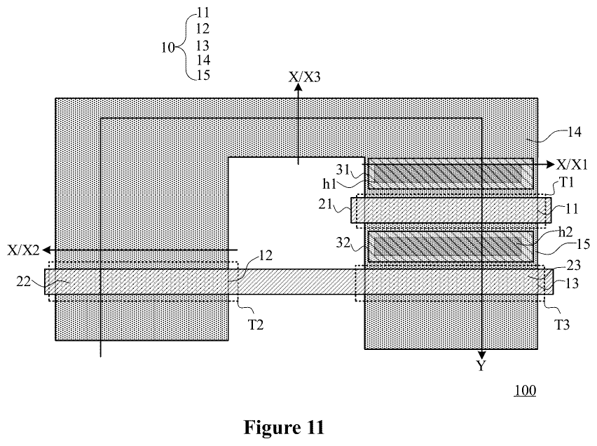

In some embodiments, as shown in FIGS. 9 and 10, the array substrate 100 further includes a third gate 23 and a second metal part 32, and the semiconductor pattern 10 may further include a third channel 13 and a second connection part 15.

The third gate 23 is located at one side of the first gate 21 away from the second gate 22 in the extension direction of the semiconductor pattern 10. The third channel 13 overlaps with the third gate 23, and the second connection part 15 connects the first channel 11 and the third channel 13. The second metal part 32 overlaps with the second connection part 15, and the second metal part 32 is electrically connected to the second connection part 15. A transistor T3 may include the third gate 23 and the third channel 13.

In the embodiment, in the extension direction of the semiconductor pattern 10, the first connection part 14 and the second connection part 15 are respectively connected to both sides of the first channel 11. In one embodiment, the first connection part 14 is electrically connected to the first metal part 31, and the second connection part 15 is electrically connected to the second metal part 32. The transistor T1 includes the first channel 11 and the first gate 21. In this way, a square resistance of the connection parts respectively connected to both ends of the transistor T1 is reduced, and a current transmitting ability of the transistor T1 can be improved, which is more beneficial to improving the uniformity of current in the transistor T1, to improve the performance of the transistor T1 and a consistency between the actual performance and the simulation performance of the transistor T1, which is beneficial to improving the display quality in a case that the array substrate is used in a display panel.

A circuit in the array substrate may include a pixel circuit configured to drive a light emitting device to emit light.

For example, the transistor T1 may be a driving transistor in a pixel circuit.

The first channel 11, the second channel 12, and the third channel 13 may include an original semiconductor material, and the first connection part 14 and the second connection part 15 may be structures formed after the original semiconductor material is implanted with ions. In a thickness direction of the array substrate, film layer positions of the first channel 11, the second channel 12, the third channel 13, the first connection part 14 and the second connection part 15 may be the same.

For example, a conductivity of the second metal part 32 may be greater than a conductivity of the second connection part 15.

For example, the conductivity of the second metal part 32 may be equal to the conductivity of the first metal part 31. The conductivity of the second connection part 15 may be equal to the conductivity of the first connection part 14.

For example, a potential of the second metal part 32 is floating. Here, “floating potential” means that the second metal part 32 is not electrically connected to other structures except the second connection part 15. Viewing from a metal layer where the second metal part 32 is located, the second metal part 32 is an isolated pattern. That is, the second metal part 32 is electrically connected only to the second connection part 15, and the potential of the second metal part 32 is the same as a potential of the second connection part 15.

For example, a size of the second metal part 32 in a first direction X is larger than a size of the second metal part 32 in a second direction Y, the first direction X intersects with the extension direction of the semiconductor pattern 10, and the second direction Y is the same as the extension direction of the semiconductor pattern 10.

For example, a size of the second metal part 32 in the first direction X is smaller than or equal to a size of the second connection part 15 in the first direction X. An orthographic projection of the second metal part 32 on a plane where the semiconductor pattern 10 is located may be within the semiconductor pattern 10.

For example, in the extension direction of the semiconductor pattern 10, an interval between the first metal part 31 and the first gate 21 is equal to an interval between the second metal part 32 and the first gate 21.

In some embodiments, as shown in FIGS. 9 and 10, the first metal part 31 is electrically connected to the first connection part 14 through a first via hole h1, and the second metal part 32 is electrically connected to the second connection part 15 through a second via hole h2. The first via hole h1 and the second via hole h2 are symmetrically distributed. In this way, a conductivity of both ends of the first channel 11 tends to be consistent, which is more beneficial to the uniformity of current in the transistor T1.

As an example, as shown in FIG. 9, multiple first via holes h1 may be arranged in a first direction X, and multiple second via holes h2 may also be arranged in the first direction X.

In a case that the first via hole h1 and the second via hole h2 are symmetrically distributed, orthographic projections of the first via hole h1 and the second via hole h2 on a plane where the semiconductor pattern 10 is located may have a same shape.

As another example, as shown in FIG. 11, an orthographic projection of the first via hole h1 on the plane where the semiconductor pattern 10 is located may be strip-shaped, and the strip-shaped orthographic projection of the first via hole h1 on the plane where the semiconductor pattern 10 is located extends in the first direction X. An orthographic projection of the second via hole h2 on the plane where the semiconductor pattern 10 is located may also be strip-shaped, and the strip-shaped orthographic projection of the second via hole h2 on the plane where the semiconductor pattern 10 is located extends in the first direction X.

Of course, in other examples, the first via hole h1 and the second via hole h2 may also be asymmetrically distributed. Orthographic projections of the first via hole h1 and the second via hole h2 on the plane where the semiconductor pattern 10 is located may have different shapes.

In addition, in other examples, there may be no other film layer between the second metal part 32 and the second connection part 15. That is, the second metal part 32 may be in direct contact with the second connection part 15 (not shown in the drawings). In this case, there is no need to set a connection via hole between the second metal part 32 and the second connection part 15, which may be electrically connected through direct contact.

It is found by inventors from research that a transistor with a large width-to-length ratio of a channel is prone to a problem of uneven current distribution in an on state. In some embodiments, in a case that a width of the channel of the transistor is greater than or equal to um, the transistor is more prone to the problem of uneven current distribution in the on state.

In some embodiments, a width of the first channel 11 is greater than or equal to 10 um, and/or a width of the second channel 12 is greater than or equal to 10 um. A transistor in which the first channel 11 and/or the second channel 12 is located is prone to the problem of uneven current distribution. Therefore, the first metal part 31 is provided corresponding to the first channel 11 and/or the second channel 12, to improve the uniformity of current in the transistor.

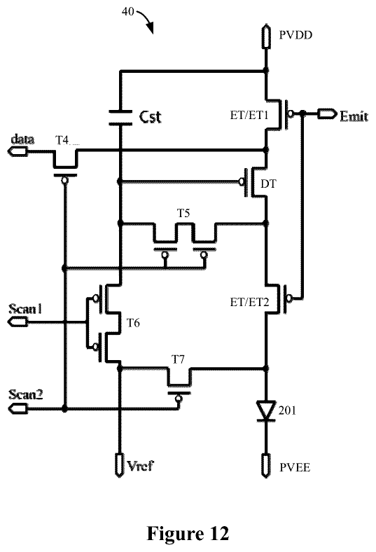

In some embodiments, as shown in FIG. 12, the array substrate includes a pixel circuit 40 including a driving transistor DT and a light emitting control transistor ET. The light emitting control transistor ET may include a first light emitting control transistor ET1 and a second light emitting control transistor ET2. The transistor T1 in the above example may be the driving transistor DT, and the driving transistor DT may include the first gate 21 and the first channel 11. The transistor T2 in the above example may be the light emitting control transistor ET. For example, the transistor T2 in the above example may be any one of the first light emitting control transistor ET1 and the second light emitting control transistor ET2. The light emitting control transistor ET may include the second gate 22 and the second channel 12.

In a case that the first light emitting control transistor ET1 and the second light emitting control transistor ET2 are turned on, a driving current generated by the driving transistor DT may be transmitted to a light emitting device 201 to drive the light emitting device 201 to emit light.

The light emitting control transistor ET, the driving transistor DT and the light emitting device 201 may be connected between a first power line PVDD and a second power line PVEE. The first power line PVDD may be used to provide positive polarity voltage, and the second power line PVEE may be used to provide negative polarity voltage. In a case that the light emitting device 201 emits light, current flows from the first power line PVDD to the second power line PVEE. That is, in a case that the light emitting device 201 emits light, the current passes through the light emitting control transistor ET and the driving transistor DT. Therefore, the uniformity of current of the driving transistor DT and the light emitting control transistor ET plays an important role in the display quality.

In an embodiment of the present disclosure, the driving transistor DT includes the first gate 21 and the first channel 11, and the light emitting control transistor ET includes the second gate 22 and the second channel 12. In this case, the first connection part 14 is connected between the driving transistor DT and the light emitting control transistor ET, the first metal part 31 is electrically connected to the first connection part 14, where the first metal part 31 may be used to improve the uniformity of current in the driving transistor DT and the light emitting control transistor ET. Thus, in a case that the array substrate is used in a display panel, the display quality can be improved.

In some embodiments, as shown in FIG. 12, the pixel circuit 40 may further include a first transistor which is a transistor other than the driving transistor DT and the light emitting control transistor ET. For example, the pixel circuit 40 may include a data writing transistor T4, a threshold compensation transistor T5, a first reset transistor T6 and a second reset transistor T7. The first transistor may include at least one of the data writing transistor T4, the threshold compensation transistor T5, the first reset transistor T6 and the second reset transistor T7.

A width-to-length ratio of a channel of the driving transistor DT may be greater than a width-to-length ratio of a channel of the first transistor, and/or a width-to-length ratio of a channel of the light emitting control transistor ET may be greater than a width-to-length ratio of a channel of the first transistor.

On the one hand, the width-to-length ratios of the channels of the driving transistor DT and/or the light emitting control transistor ET being larger than width-to-length ratios of channels of other transistors in the pixel circuit may meet the requirements of the light emitting device 201 for large working current. On the other hand, with the development of display technologies, people demand higher and higher resolution. For example, more pixel circuits are required to be set in a space of unit area to improve the resolution. The width-to-length ratios of the channels of the driving transistor DT and/or the light emitting control transistor ET is larger than width-to-length ratios of channels of other transistors in the pixel circuit, and width-to-length ratios of channels of only some transistors are increased, which is beneficial to improving the uniformity of large working current without reducing the resolution.

For example, width-to-length ratios of channels of the driving transistor DT and the light emitting control transistor ET may be equal. Width-to-length ratios of channels of the data writing transistor T4, the threshold compensation transistor T5, the first reset transistor T6 and the second reset transistor T7 may be equal. It should be noted that “equal” here may include a parameter difference caused by a process error. That is, if the difference between width-to-length ratios of channels of the two transistors is within a process error range, it may be considered that width-to-length ratios of channels of the two transistors are equal.

For example, a width of the channel of the driving transistor DT may be smaller than a width of the channel of the light emitting control transistor ET. Of course, in other examples, the width of the channel of the driving transistor DT may be greater than or equal to the width of the channel of the light emitting control transistor ET.

For example, a length of the channel of the driving transistor DT may be different from lengths of channels of other transistors in the pixel circuit. Except the driving transistor DT, the lengths of the channels of other transistors in the pixel circuit may be the same. Of course, the length of the channel of each transistor may also be set as required.

For example, a first electrode of the data writing transistor T4 may be connected to a data line data, a second electrode of the data writing transistor T4 may be connected to a first electrode of the driving transistor DT, and a gate of the data writing transistor T4 may be connected to a second scanning line Scan2.

A first electrode of the threshold compensation transistor T5 may be connected to a second electrode of the driving transistor DT, a second electrode of the threshold compensation transistor T5 may be connected to a gate of the driving transistor DT, and a gate of the threshold compensation transistor T5 may be connected to the second scanning line Scan2. The gate of the driving transistor DT is the first gate.

A first electrode of the first reset transistor T6 may be connected to a reset signal line Vref, a second electrode of the first reset transistor T6 may be connected to the gate of the driving transistor DT, and a gate of the first reset transistor T6 may be connected to a first scanning line Scan1.

A first electrode of the second reset transistor T7 may be connected to the reset signal line Vref, a second electrode of the second reset transistor T7 may be connected to an anode of the light emitting device 201, and a gate of the second reset transistor T7 may be connected to the second scanning line Scan2.

In addition, a gate of the light emitting control transistor ET is connected to a light emitting control signal line Emit, and the gate of the light emitting control transistor ET includes the second gate.

It should be noted that in FIG. 12, description is made by taking a case in which both the first reset transistor T6 and the second reset transistor T7 are connected to the reset signal line Vref as an example, However, the first reset transistor T6 and the second reset transistor T7 may, in one embodiment, be connected to different signal lines, to provide different reset signals for the gate of the driving transistor DT and the anode of the light emitting device 201, thus meeting different reset requirements of the driving transistor DT and the light emitting device 201.

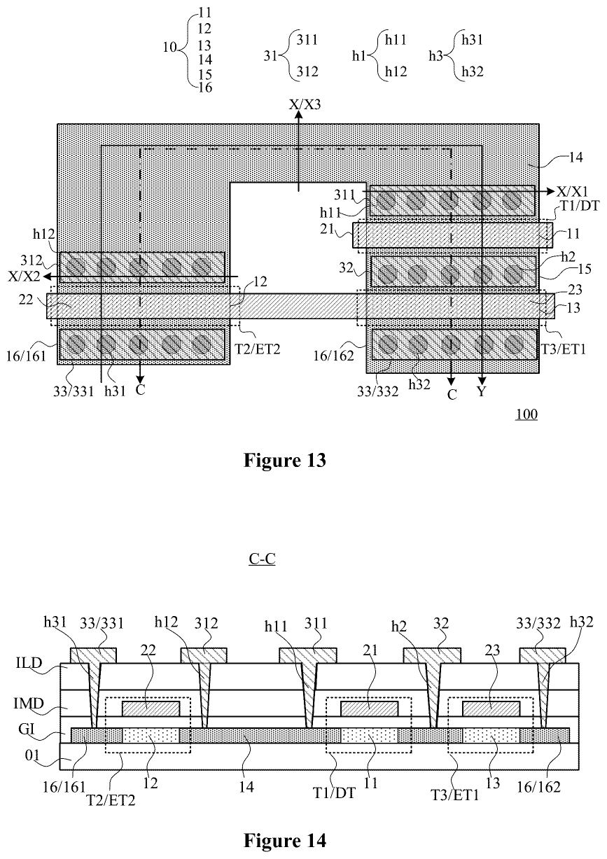

In some embodiments, as shown in FIGS. 13 and 14, the semiconductor pattern 10 may further include an electrode connection part 16 which is located at one side of the second channel 12 away from the first connection part 14 in the extension direction of the semiconductor pattern 10. The array substrate may further include an electrode metal part 33 which overlaps with the electrode connection part 16 and is electrically connected to the electrode connection part 16. The electrode metal part 33 is electrically connected to a signal trace or an electrode of a light emitting device.

In the embodiment, in the extension direction of the semiconductor pattern 10, the first connection part 14 and the electrode connection part 16 are respectively connected to both sides of the second channel 12. In one embodiment, the first connection part 14 is electrically connected to the first metal part 31, and the electrode connection part 16 is electrically connected to the electrode metal part 33. The transistor T2 includes the second channel 12 and the second gate 22. In this way, the square resistances of the connection parts respectively connected to both ends of the transistor T2 are reduced, and a current transmitting ability of the transistor T2 can be improved, to improve the uniformity of current in the transistor T2, improving the performance of the transistor T2 and a consistency between the actual performance and the simulation performance of the transistor T2, which is beneficial to improving the display quality in a case that the array substrate is used in a display panel.

For example, a conductivity of the electrode metal part 33 may be greater than a conductivity of the electrode connection part 16.

For example, the conductivity of the electrode metal part 33, the conductivity of the second metal part 32, and the conductivity of the first metal part 31 may be equal. The conductivity of the electrode connection part 16, the conductivity of the second connection part 15 and the conductivity of the first connection part 14 may be equal.

It is to be understood that a potential of the electrode metal part 33 is not floating since the electrode metal part 33 is electrically connected to the signal trace or the electrode of the light emitting device.

For example, the electrode connection part 16 may include a first electrode connection part 161 and a second electrode connection part 162. In the extension direction of the semiconductor pattern 10, the first electrode connection part 161 is located at one side of the second channel 12 away from the first connection part 14, and the second electrode connection part 162 is located at one side of the third channel 13 away from the first connection part 14.

The electrode metal part 33 may include a first electrode metal part 331 and a second electrode metal part 332. The first electrode metal part 331 overlaps with the first electrode connection part 161, and the first electrode metal part 331 is electrically connected to the first electrode connection part 161. The second electrode metal part 332 overlaps with the second electrode connection part 162, and the second electrode metal part 332 is electrically connected to the second electrode connection part 162.

The transistor T2 including the second channel 12 and the second gate 22 may include the second light emitting control transistor ET2. In this case, the first electrode metal part 331 may be electrically connected to the electrode of the light emitting device.

The transistor T3 including the third channel 13 and the third gate 23 may include the first light emitting control transistor ET1. In this case, the second electrode metal part 332 may be electrically connected to the first power line PVDD.

In some embodiments, as shown in FIGS. 13 and 14, the first metal part 31 is electrically connected to the first connection part 14 through a first via hole h1, and the electrode metal part 33 is electrically connected to the electrode connection part 16 through a third via hole h3. It is to be understood that in this case, other film layers may be arranged between the electrode metal part 33 and the electrode connection part 16.

For example, the first metal part 31 and the electrode metal part 33 may be located in a same film layer.

An orthographic projection of the third via hole h3 on a plane where the semiconductor pattern 10 is located may have a circular shape, a strip shape or a polygonal shape, and the polygonal shape may include an octagon.

The orthographic projection of the third via hole h3 on the plane where the semiconductor pattern 10 is located and the orthographic projection of the first via hole h1 on the plane where the semiconductor pattern 10 is located may have the same or different shapes.

For example, the first via hole h1 may include a first sub-via hole h11 connecting the first sub-metal part 311 with the first connection part 14 and a second sub-via hole h12 connecting the second sub-metal part 312 with the first connection part 14.

The third via hole h3 may include a third sub-via hole h31 connecting the first electrode connection part 161 with the first electrode metal part 331 and a fourth sub-via hole h32 connecting the second electrode connection part 162 with the second electrode metal part 332.

In some embodiments, as shown in FIG. 12, the array substrate includes a pixel circuit 40 including a storage capacitor Cst and a driving transistor DT. As shown in FIGS. and 16, the storage capacitor Cst includes a first electrode plate c11 and a second electrode plate c12, the driving transistor DT includes the first gate 21 and the first channel 11, and the first electrode plate c11 is electrically connected to the first gate 21 of the driving transistor DT. Second electrode plates c12 of storage capacitors Cst in different pixel circuits 40 may be connected through a connection line c13. The first metal part 31 does not overlap with the connection line c13. Here, “not overlapping” means that orthographic projections of the first metal part 31 and the connection line c13 on a plane where the array substrate is located do not overlap with each other.

As described above, the first metal part 31 may be electrically connected to the first connection part 14 through the first via hole h1. In a case that the first metal part 31 does not overlap with the connection line c13, the first via hole h1 may be prevented from passing through the connection line c13, to reduce the signal interference between the first via hole h1 and the connection line c13.

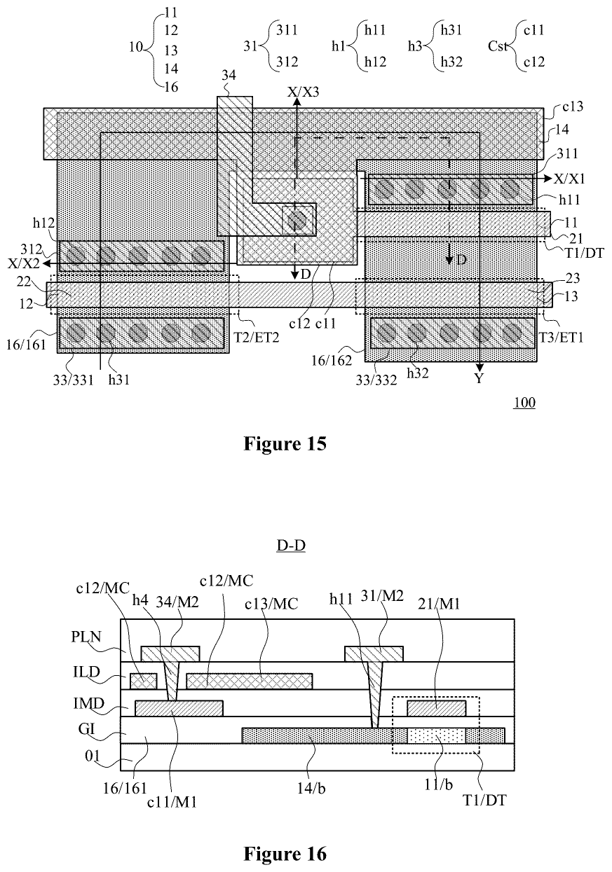

In some embodiments, as shown in FIGS. 15 and 16, an extension direction of the connection line c13 intersects with a direction in which the first channel 11 and the first metal part 31 are arranged, and the first metal part 31 is located between the first channel 11 and the connection line c13 in a direction parallel to a plane of the array substrate. In this way, the first metal part 31 may be arranged close to the first channel 11, which is beneficial to improving the ability of the first metal part 31 to improve the uniformity of current in the transistor T1.

In some embodiments, as shown in FIG. 16, the array substrate may include a substrate 01 and a driving device layer 02 on the substrate 01. The driving device layer 02 may include a semiconductor layer b, a first metal layer M1, a capacitor metal layer MC and a second metal layer M2 which are stacked. The semiconductor layer b is located between the substrate 01 and the first metal layer M1, the capacitor metal layer MC is located at one side of the first metal layer M1 away from the semiconductor layer b, and the second metal layer M2 is located at one side of the capacitor metal layer MC away from the first metal layer M1.

For example, a gate insulating layer GI may be disposed between the first metal layer M1 and the semiconductor layer b. A capacitor insulating layer IMD may be disposed between the first metal layer M1 and the capacitor metal layer MC. An interlayer dielectric layer ILD may be disposed between the capacitor metal layer MC and the second metal layer M2. The array substrate may further include a planarization layer PLN covering the second metal layer M2.

For example, a material of the first metal layer M1 may include molybdenum (Mo), and a material of the capacitor metal layer MC may include molybdenum (Mo). The second metal layer M2 may include multiple sub-metal layers which are stacked. For example, the second metal layer M2 may include titanium/aluminum/titanium (Ti/Al/Ti) metal layers which are stacked. A conductivity of the second metal layer M2 may be greater than a conductivity of the first metal layer M1 and a conductivity of the capacitor metal layer MC.

The semiconductor pattern 10 may be located in the semiconductor layer b. The first gate 21 and the second gate 22 may be located in the first metal layer M1. One of electrode plates of a capacitor Cst of the pixel circuit is located in the capacitor metal layer MC. For example, the second electrode plate c12 of the storage capacitor Cst is located in the capacitor metal layer MC.

The first metal part 31 may be located in the second metal layer M2. The conductivity of the second metal layer M2 may be larger. A conductivity of the first metal part 31 may be improved in a case that the first metal part 31 is located in the second metal layer M2.

For example, the second metal part 32 in the above example may, in one embodiment, be located in the second metal layer M2. The second metal layer M2 may be provided with the electrode metal part 33.

For example, the array substrate may further include a bridge metal part 34. One end of the bridge metal part 34 may be electrically connected to the first gate 21 of the driving transistor DT through a fourth via hole h4, and the other end of the bridge metal part 34 may be electrically connected to the threshold compensation transistor T5 and the first reset transistor T6.

For example, for a transistor provided with a source and/or a drain in the pixel circuit, the source and/or the drain of the transistor may be located in the second metal layer M2.

For example, the first electrode plate c11 of the storage capacitor Cst may be located in the first metal layer M1. The connection line c13 may be located in the capacitor metal layer MC.

In some embodiments, the first metal part 31 includes titanium/aluminum/titanium metal layers which are stacked. In this way, the conductivity of the first metal part 31 can further be improved.

For example, the second metal part 32 in the above example also includes titanium/aluminum/titanium metal layers which are stacked.

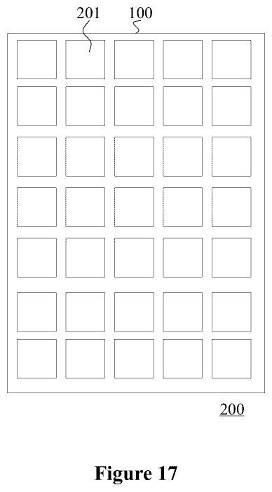

In one embodiment, a display panel is further provided according to the present disclosure FIG. 17 shows a schematic structural diagram of a display panel according to an embodiment of the present disclosure. As shown in FIG. 17, a display panel 200 according to an embodiment of the present disclosure may include the array substrate according to any one of the above embodiments. The display panel 200 may further include a light emitting device 201. A pixel circuit in the array substrate is configured to drive the light emitting device to emit light.

The light emitting device 201 may include a Micro LED. In one embodiment, the light emitting device 201 may include an Organic Light-Emitting Diode (OLED). In one embodiment, the light emitting device 201 may include an LED. In one embodiment, the light emitting device 201 may be other types of light emitting devices.

The display panel according to the embodiment of the present disclosure has the beneficial effects of the array substrate according to the embodiment of the present disclosure. For details, reference may be made to the specific descriptions of the array substrate in the above embodiments, which is not repeated here.

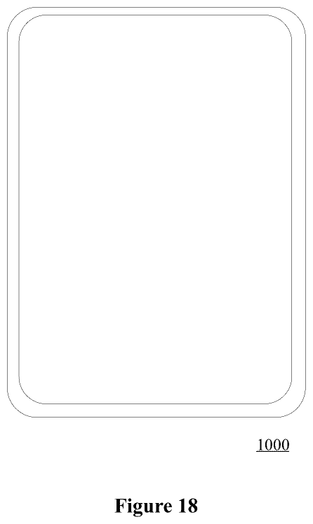

In one embodiment, a display device is further provided according to the present disclosure, which includes the display panel according to the present disclosure. Reference is made to FIG. 18, which is a schematic structural diagram of a display device according to an embodiment of the present disclosure. A display device 1000 in FIG. 18 includes the display panel 200 according to any one of the above embodiments of the present disclosure. In the embodiment shown in FIG. 18, a mobile phone is taken as an example to describe the display device 1000. It is to be understood that the display device according to the embodiment of the present disclosure may be a wearable product, a computer, a television, a vehicle-mounted display device or other display device with a display function, which is not limited in the present disclosure. The display device according to the embodiment of the present disclosure has the beneficial effects of the display panel according to the embodiment of the present disclosure. For details, reference may be made to the specific descriptions of the display panel in the above embodiments, which is not repeated here.

The embodiments according to the present disclosure are described as above, and not all details are described in detail in the embodiments. The present disclosure is not limited to the specific embodiments. Apparently, various modifications and variations may be made based on the above description. These embodiments are selected and described in detail in this specification for explaining the principles and practical applications of the present disclosure, and those skilled in the art can make good use of the present disclosure and make modifications based on the present disclosure. The present disclosure is limited only by the claims, the full scope and equivalents thereof.

What is claimed is:

1. An array substrate, comprising:
a semiconductor pattern, a first gate, a second gate and a first metal part,
wherein the semiconductor pattern comprises a first channel overlapping with the first gate, a second channel overlapping with the second gate, and a first connection part connecting the first channel with the second channel; and
the first metal part overlaps with the first connection part and is electrically connected to the first connection part.

2. The array substrate according to claim 1, wherein
a conductivity of the first metal part is greater than a conductivity of the first connection part, and/or
a potential of the first metal part is floating.

3. The array substrate according to claim 1, wherein
a size of the first metal part in a first direction is larger than a size of the first metal part in a second direction, the first direction intersects with an extension direction of the semiconductor pattern, and the second direction is the same as the extension direction of the semiconductor pattern, or
a size of the first metal part in a first direction is smaller than or equal to a size of the first connection part in the first direction, and the first direction intersects with an extension direction of the semiconductor pattern.

4. The array substrate according to claim 1, wherein
the first metal part is spaced from the first gate by an interval d1 in an extension direction of the semiconductor pattern, or the first metal part is spaced from the second gate by the interval d1 in the extension direction of the semiconductor pat, wherein 1 um≤d1≤5 um.

5. The array substrate according to claim 1, wherein
the first metal part comprises a first sub-metal part and a second sub-metal part which are spaced apart from each other;
in an extension direction of the semiconductor pattern, a distance between the first sub-metal part and the first channel is smaller than a distance between the first sub-metal part and the second channel, and a distance between the second sub-metal part and the second channel is smaller than a distance between the second sub-metal part and the first channel.

6. The array substrate according to claim 1, wherein
the first metal part is electrically connected to the first connection part through a first via hole.

7. The array substrate according to claim 6, wherein
a plurality of first via holes are provided, and are arranged in a first direction, and the first direction intersects with an extension direction of the semiconductor pattern.

8. The array substrate according to claim 6, wherein
the first via hole has a strip shape, and an extension direction of the strip shape intersects with an extension direction of the semiconductor pattern.

9. The array substrate according to claim 1, further comprising:
a third gate located at one side of the first gate away from the second gate in an extension direction of the semiconductor pattern,
wherein the semiconductor pattern further comprises a third channel overlapping with the third gate and a second connection part connecting the first channel and the third channel; and
the array substrate further comprises a second metal part which overlaps with the second connection part and is electrically connected to the second connection part.

10. The array substrate according to claim 9, wherein
the first metal part is electrically connected to the first connection part through a first via hole;
the second metal part is electrically connected to the second connection part through a second via hole; and
the first via hole and the second via hole are symmetrically distributed.

11. The array substrate according to claim 1, wherein
a width of the first channel is greater than or equal to 10 um, and/or a width of the second channel is greater than or equal to 10 um.

12. The array substrate according to claim 1, further comprising:
a pixel circuit comprising a driving transistor and a light emitting control transistor, wherein the driving transistor comprises the first gate and the first channel, and the light emitting control transistor comprises the second gate and the second channel.

13. The array substrate according to claim 12, wherein
the semiconductor pattern further comprises an electrode connection part which is located at one side of the second channel away from the first connection part in an extension direction of the semiconductor pattern;
the array substrate further comprises an electrode metal part which overlaps with the electrode connection part and is electrically connected to the electrode connection part; and
the electrode metal part is electrically connected to a signal trace or an electrode of a light emitting device.

14. The array substrate according to claim 13, wherein
the first metal part is electrically connected to the first connection part through a first via hole, and the electrode metal part is electrically connected to the electrode connection part through a third via hole.

15. The array substrate according to claim 12, wherein the pixel circuit further comprises a first transistor, a width-to-length ratio of a channel of the driving transistor is greater than a width-to-length ratio of a channel of the first transistor, and/or a width-to-length ratio of a channel of the light emitting control transistor is greater than a width-to-length ratio of a channel of the first transistor.

16. The array substrate according to claim 1, further comprising:
a substrate; and
a driving device layer on the substrate, wherein the driving device layer comprises a semiconductor layer, a first metal layer, a capacitor metal layer and a second metal layer which are stacked, the semiconductor layer is located between the substrate and the first metal layer, the capacitor metal layer is located at one side of the first metal layer away from the semiconductor layer, and the second metal layer is located at one side of the capacitor metal layer away from the first metal layer,
wherein the semiconductor pattern is located in the semiconductor layer;
the first gate and the second gate are located in the first metal layer;
one of electrode plates of a capacitor of the pixel circuit is located in the capacitor metal layer; and
the first metal part is located in the second metal layer.

17. The array substrate according to claim 1, further comprising:
a pixel circuit comprising a storage capacitor and a driving transistor, wherein the storage capacitor comprises a first electrode plate and a second electrode plate, the driving transistor comprises the first gate and the first channel, and the first electrode plate is electrically connected to the first gate of the driving transistor,
wherein second electrode plates of storage capacitors in different pixel circuits are connected through a connection line; and
the first metal part does not overlap with the connection line.

18. The array substrate according to claim 17, wherein an extension direction of the connection line intersects with a direction in which the first channel and the first metal part are arranged, and the first metal part is located between the first channel and the connection line in a direction parallel to a plane of the array substrate.

19. A display panel, comprising an array substrate and a light emitting device, wherein
the array substrate comprises a semiconductor pattern, a first gate, a second gate and a first metal part, wherein
the semiconductor pattern comprises a first channel overlapping with the first gate, a second channel overlapping with the second gate, and a first connection part connecting the first channel with the second channel;
the first metal part overlaps with the first connection part and is electrically connected to the first connection part; and
a pixel circuit in the array substrate is configured to drive the light emitting device to emit light.

20. A display device comprising a display panel, wherein the display panel comprises an array substrate and a light emitting device, wherein
the array substrate comprises a semiconductor pattern, a first gate, a second gate and a first metal part, wherein
the semiconductor pattern comprises a first channel overlapping with the first gate, a second channel overlapping with the second gate, and a first connection part connecting the first channel with the second channel;
the first metal part overlaps with the first connection part and is electrically connected to the first connection part; and
a pixel circuit in the array substrate is configured to drive the light emitting device to emit light.
